(19) United States
(12) Patent Application Publication
(10) Pub. No.: US 2004/0013004 A1
(43) Pub. Date: Jan. 22, 2004

(54) Lower power consuming sense amplifier

(76) Inventor: Kwok K. Hung, Fremont, CA (US)

Correspondence Address: Timothy N. Trop, TROP, PRUNER & HU, P.C., Ste. 100, 8554 Katy Freeway, Houston, TX, 77024, US

(21) Appl. No.: 10/198,454

(22) Filed: Jul. 18, 2002

(51) Int. Cl. G11C 5/00

(52) U.S. Cl. 365/189.07

(57) ABSTRACT

A fixed current source may be utilized to provide a sense amplifier which is insensitive to changes in supply voltage. As a result, the tradeoff between speed and power consumption may be engineered to achieve desired objectives.

### BACKGROUND

This invention relates generally to semiconductor memories and, particularly, to sense amplifiers for semiconductor memories.

Semiconductor memories may be utilized to store information in a plurality of memory cells. Semiconductor memories include volatile and non-volatile memories. Volatile memories include dynamic random access memories (DRAM). Non-volatile memories include erasable, programmable, read only memories (EPROMs) and flash memories, to mention a couple of examples.

Generally, an array of memory cells in a semiconductor memory may be arranged in rows and columns. A particular memory cell in a row and a column may be addressed. When that cell is addressed, it may be coupled to a sense amplifier. The sense amplifier may compare the electrical information stored on the cell to a reference in order to enable the programmed state of the cell to be determined.

Generally, the more power that the sense amplifier draws, the greater the power consumption of the semiconductor memory. In a number of applications and, particularly, those involving battery power sources, the power consumption of the semiconductor memory may be very critical.

Thus, it is desirable to provide a semiconductor memory that reduces the power consumption.

### BRIEF DESCRIPTION OF THE DRAWINGS

FIG. 1 is a schematic depiction of one embodiment of the present invention;

FIG. 2A is a graph of hypothetical bitline potential versus time in one embodiment of the present invention;

FIG. 2B is a graph of hypothetical potential on the node NA in FIG. 1 versus time in accordance with one embodiment of the present invention;

FIG. 2C is a graph of current through the transistors 22 and 24 over time in one hypothetical embodiment of the present invention; and

FIG. 3 is a depiction of another embodiment of the present invention.

### DETAILED DESCRIPTION

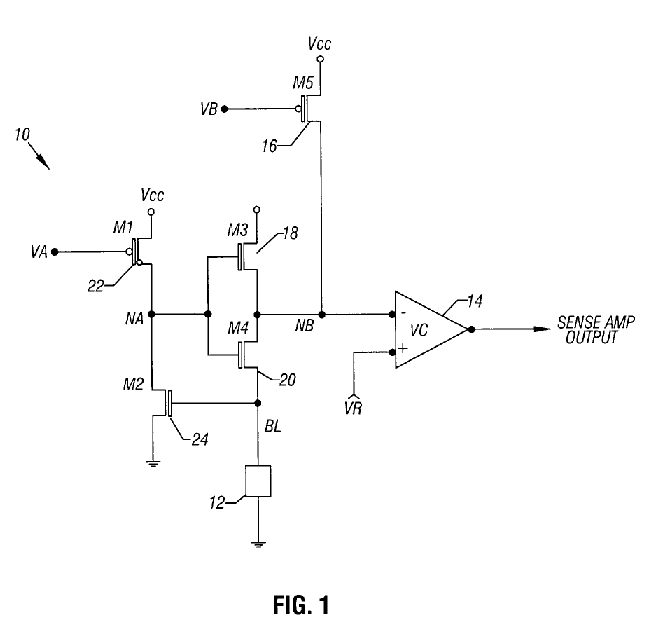

Referring to FIG. 1, a semiconductor memory 10 may include a sense amplifier coupled to a memory cell 12. The memory cell 12 may be an addressed memory cell in an array that includes a large number of memory cells arranged in rows and columns. The memory cell 12 may be part of a bitline (BL) coupled to the sense amplifier.

The sense amplifier may include a voltage comparator 14 that provides the sense amplifier output. The comparator 14 compares an indication of the potential on the bitline, which is indicative of the state of the memory cell, to a reference voltage (VR) in one embodiment.

A fixed voltage source VA may bias the gate of a PMOS transistor 22. The PMOS transistor 22 has its source coupled to the supply voltage and its drain coupled to the node NA. Also coupled to the node NA is an NMOS transistor 24 whose source is coupled to ground. The gate of the transistor 24 may be coupled to the bitline node.

The bitline node is also coupled to the NMOS transistor 20. The gate of the NMOS transistor 20 is coupled to the node NA. The drain of the transistor 20 is coupled to the node NB that is also coupled to the comparator 14. Also coupled to the nodes NA and NB is a transistor 18 whose drain is coupled to the supply potential.

The PMOS transistor 16 may be coupled to a voltage source VB. Its source may be coupled to the supply voltage and its drain may be coupled to the node NB.

Since the voltage VA is a fixed bias voltage applied to the gate of the transistor 22, the drain current of the transistor 22 is fixed by the bias potential VA. At the start of sensing, the bitline (BL) voltage may be zero volts and the current through the transistor 24 may also be zero.

The voltage at node A is pulled up to V_{cc} by the action of the transistor 22. Both transistors 18 and 20 are turned on strongly to charge up the bitline (BL). As the BL voltage rises, the current through the transistor 24 increases and the voltage on the node NA decreases.

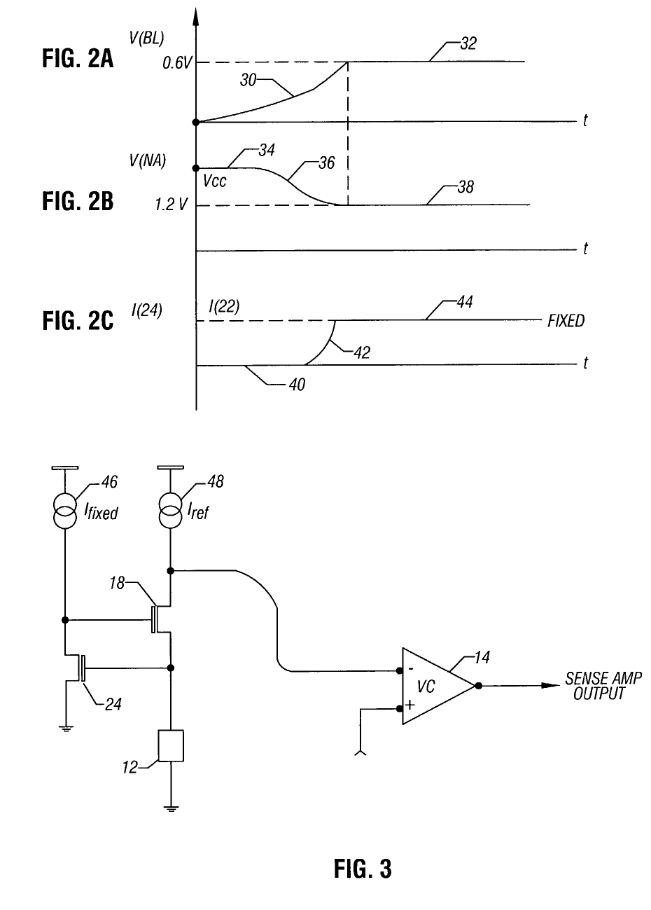

Thus, referring to FIG. 2A, during a precharge period indicated at 30, the voltage BL begins to rise. At the same time the voltage on the node NA is linear in the region 34 and then begins to fall as indicated at 36 in FIG. 2B.

The voltage BL reaches a stable value indicated at 32 in FIG. 2A when the current through the transistor 24 is approximately equal to the current through the transistor 22. Thus, referring to FIG. 2C, the current through the transistor 22 indicated as I(22) and the current through the transistor 24 are equal at the beginning of the fixed current level 44. Prior thereto, the current through the transistor 24 was substantially zero, as indicated at 40, and then it rises abruptly, as indicated at 42, to the level 44, where it equals the current through the transistor 22.

At this point, the current through the transistors 22 and 24 is fixed. Thus, the final bitline voltage is also controlled by the fixed supply potential VA.

The total current consumption in the circuit is equal to the sum of the currents through the transistors 22, 18, and 16, together with the current to the voltage comparator 14. The current of the transistor 22 is fixed by the potential VA and can be adjusted according to the desired power consumption or circuit speed.

The current in the transistor 16 is a reference current. The current through transistor 18 is equal to the difference between the cell current and the reference current. Since the cell current is specified by the specific technology, the current consumption of the sense amplifier is fixed by the voltage VA and is independent of the supply voltage V_{cc}.

In some sense amplifiers, the bias supplied to a transistor, such as the transistor 22, is a sensitive function of the supply voltage. For applications with a wide range of potential supply voltages, the current through the transistors 22 and 24 may increase by several times from the low end of supply voltage to the high end of supply voltage. Since sensing speed is a function of the bias current, the sensing speed will also be sensitive to the supply voltage.

Sense amplifiers may be designed to operate at a wide range of available supply voltages that may be encountered with particularly products. With the design showing FIG. 1, with the fixed supply voltage, the current consumption is independent of the supply voltage and the sensing speed is also independent of the supply voltage.

In one embodiment, the sensing may be done by comparing the cell current with a fixed reference current. The cell may be considered to be in a state one when its current is larger than the reference current. The cell is considered to be in a state zero when its current is smaller than the reference current.

The gate of the transistor 22 is biased by the fixed supply potential VA providing the bias current for the circuit to operate. The transistor 16 with its gate biased at VB provides a reference current to be compared with the cell current. The transistors 24 and 20 form a feedback circuit to maintain a constant voltage on the bitline (BL) of the memory cell 12.

Due to the feedback action of the transistors 24 and 20, the voltage at NA rises to about the supply voltage. This turns on the transistor 18 to precharge the bitline. When the bitline voltage has risen to a certain value, the transistor 18 shuts off. The voltage at NB is determined by the reference current and the cell current. By comparing the voltage at NB with a predetermined reference voltage (VR) the circuit detects the state of a memory cell.

Referring to FIG. 3, an equivalent circuit is shown wherein the transistor 22 and the fixed supply potential VA are indicated as a fixed current source 46. Similarly, the potential VB and the transistor 16 are indicated by a fixed current source 48.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
using a fixed current to control the potential on a node coupled to a memory cell; and
sensing a characteristic related to the potential on said node.

2. A method comprising:
using a fixed potential to control the potential on a node coupled to a memory cell; and
sensing a characteristic related to the potential on said node.

3. A sense amplifier comprising:
a node coupled to a memory cell;
a circuit coupled to a fixed bias potential, said circuit to control the voltage on said node; and
a sensing circuit to sense a characteristic related to the potential on said node.
